(19) United States
(12) Patent Application Publication
(10) Pub. No.: US 2026/0171348 A1
(43) Pub. Date: Jun. 18, 2026

(54) SHIELDED IRRADIATOR VEHICLE

(71) Applicant: FERMI RESEARCH ALLIANCE, LLC, Chicago, IL (US)

(72) Inventor: Thomas Kroc, Batavia, IL (US)

(21) Appl. No.: 19/121,371

(22) PCT Filed: Oct. 20, 2023
(86) PCT No.: PCT/US2023/035589

§ 371 Date: Apr. 15, 2025

Related U.S. Application Data
(60) Provisional application No. 63/418,459, filed on Oct. 21, 2022.

(51) Int. Cl. H01J 37/244; H01J 37/28

(52) U.S. Cl. CPC H01J 37/244; H01J 37/28

(57) ABSTRACT

Disclosed are systems and methods relating to a vehicle for roadway construction which includes radiation shielding rollers, additional radiation shielding, and a particle source configured to generate a particle beam, a beam scan horn, the beam scan horn configured to direct the terminal position of the particle beam and a control system for controlling a beam spot location of the particle beam.

### CROSS REFERENCE TO RELATED PATENT APPLICATIONS

This application claims the priority and benefit under 35 U.S.C. § 119(e) of U.S. Provisional Patent Application Ser. No. 63/418,459, filed Oct. 21, 2022, entitled “SHIELDED IRRADIATOR VEHICLE.” U.S. Provisional Patent Application Ser. No. 63/418,459 is herein incorporated by reference in its entirety.

### STATEMENT OF GOVERNMENT RIGHTS

The invention described in this patent application was made with Government support under the Fermi Research Alliance, LLC, Contract Number DE-AC02-07CH11359 awarded by the U.S. Department of Energy. The Government has certain rights in the invention.

### TECHNICAL FIELD

Embodiments are generally related to accelerators and accelerator shielding during use. Embodiments are also related to the treatment of materials. Embodiments additionally relate to methods and systems for rapid and deep pre-heating of surfaces, surface preparation, treating, and strengthening materials used to fill potholes, build roads, or provide other surface treatments. Embodiments are further related to vehicles with integrated internal and/or external shielding configured for treating roadways with radiation.

### BACKGROUND

An accelerator refers generally to an apparatus capable of accelerating charged particles, generated from a charged particle source through a high voltage generator or RF structure to impart increased energy. In some cases, the accelerator can be used to accelerate electrons. The accelerated electrons can be formed into a beam having high energy close to the speed of light.

Classic applications for electron beams include semiconductor manufacturing, welding, and other such applications. However, technological advances have expanded potential applications for particle beams. In particular, particle accelerator technology has been advanced such that high energy particle beams can be generated using equipment that fits in the back of a vehicle.

One such application is outlined in U.S. Pat. No. 9,340,931, titled “METHOD AND SYSTEM FOR IN-SITU CROSS LINKING OF POLYMERS, BITUMEN AND SIMILAR MATERIALS TO INCREASE STRENGTH, TOUGHNESS AND DURABILITY VIA IRRADIATION WITH ELECTRON BAMS FROM MOBILE ACCELERATORS,” filed Nov. 16, 2015. This patent outlines the use of a mobile accelerator to cross-link polymers in roadway material in order to fix potholes.

Unique and creative applications of portable particle beam technology lends itself to exciting technological improvements in numerous critical but somewhat stale fields. However, a major as yet unanswered question is how to manage the safety of operators and bystanders as mobile particle accelerators are used in public. Advances have given rise to a new class of very powerful accelerators capable of generating high power particle beams.

As such, there is a need in the art for methods and systems configured to control particle beams and render them fit and safe for use as further detailed herein.

### SUMMARY

The following summary is provided to facilitate an understanding of some of the innovative features unique to the embodiments disclosed and is not intended to be a full description. A full appreciation of the various aspects of the embodiments can be gained by taking the entire specification, claims, drawings, and abstract as a whole.

It is, therefore, one aspect of the disclosed embodiments to provide a method, system, and apparatus for manufacturing and/or maintaining pavement, concreate and other such material structures.

It is an aspect of the disclosed embodiments to provide methods and systems for curing material with electron beams.

It is an aspect of the disclosed embodiments to provide methods and systems for cross-linking of materials.

It is an aspect of the disclosed embodiments to provide methods and systems for rapid electron beam assisted treatment of roadways, using a vehicle with integrated shielding.

In accordance with the disclosed embodiments, a system comprises a particle source configured to generate a particle beam, a beam extraction assembly, the beam extraction assembly configured to direct the terminal position of the particle beam on a target, and a control system for controlling the beam, and a vehicle for transporting the accelerator assembly, the vehicle being configured with shielding and other safety measures.

In an embodiment, a system comprises a vehicle comprising at least one roller and a particle source configured to generate a particle beam, a beam scan horn, the beam scan horn configured to direct the terminal position of the particle beam, and a control system for controlling a beam spot location of the particle beam. In an embodiment, the particle source further comprises a particle accelerator. In an embodiment, the particle accelerator comprises an electron beam accelerator. In an embodiment, the particle beam comprises an electron beam. In an embodiment, the vehicle further comprises radiation shielding configured proximate to a terminus of the particle beam. In an embodiment, the at least one roller further comprises a first roller and a second roller. In an embodiment, each of the first roller and the second roller are hollow. In an embodiment, each of the first roller and the second roller further comprise shielding on their external surface. In an embodiment, the at least one roller further comprises a radiation shielding roller. In an embodiment, the vehicle further comprises at least one additional wheel configured for maneuvering the vehicle when not in use.

In another embodiment, a system comprises a vehicle comprising at least two shielding rollers and a particle accelerator mounted to the vehicle and oriented so that a beam from the particle accelerator points downward, s, ide skirt shielding, lower gap shielding, and a beam scan horn, the beam scan horn configured to direct the terminal position of the particle beam. In an embodiment, the particle accelerator comprises an electron beam accelerator configured to produce an electron beam. In an embodiment, each of the at least two shielding rollers further comprise shielding on their external surface. In an embodiment, the system further comprises at least one radiation sensor configured to measure radiation between the shielding rollers. In an embodiment, the system further comprises at least one camera configured to capture images between the shielding rollers. In an embodiment, of the system the vehicle further comprises a chassis and at least one additional wheel configured for maneuvering the vehicle when not in use.

In an embodiment, a system comprises a vehicle comprising at least two shielding rollers, a particle source configured to generate a particle beam, at least one additional wheel configured for maneuvering the vehicle when not in use, and a control system for controlling the vehicle and for controlling a beam spot location of the particle beam, and at least one sensor configured to measure radiation between the at least two shielding rollers. In an embodiment, the vehicle further comprises radiation shielding configured proximate to a terminus of the particle beam. In an embodiment, each of the at least two shielding roller further comprise radiation shielding rollers. In the at least one sensor comprises at least one of irradiation sensors, x-ray sensors, temperature sensors, and cameras.

### BRIEF DESCRIPTION OF THE DRAWINGS

The accompanying figures, in which like reference numerals refer to identical or functionally similar elements throughout the separate views and which are incorporated in and form a part of the specification, further illustrate the embodiments and, together with the detailed description, serve to explain the embodiments disclosed herein.

FIG. 1A depicts a shielded surface treatment vehicle, in accordance with the disclosed embodiments;

FIG. 1B depicts a perspective view of the shielded surface treatment vehicle, in accordance with the disclosed embodiments;

FIG. 2 depicts an irradiation pattern, in accordance with the disclosed embodiments;

FIG. 3 depicts another embodiment of a shielded surface treatment vehicle, in accordance with the disclosed embodiments;

FIG. 4 depicts a shielded surface treatment vehicle, in accordance with the disclosed embodiments;

FIG. 5 depicts another embodiment of a shielded surface treatment vehicle, in accordance with the disclosed embodiments;

FIG. 6 depicts another embodiment of a shielded surface treatment vehicle, in accordance with the disclosed embodiments;

FIG. 7 depicts another embodiment of a shielded surface treatment vehicle, in accordance with the disclosed embodiments;

FIG. 8A depicts a top view of shielding associated with a surface treatment vehicle, in accordance with the disclosed embodiments;

FIG. 8B depicts a side view of shielding associated with a surface treatment vehicle, in accordance with the disclosed embodiments;

FIG. 9 depicts steps in a method for treating a surface with a shielded vehicle, in accordance with the disclosed embodiments;

FIG. 10 depicts a block diagram of a computer system which is implemented in accordance with the disclosed embodiments;

FIG. 11 depicts a graphical representation of a network of data-processing devices in which aspects of the present embodiments may be implemented;

FIG. 12 depicts a computer software system for directing the operation of the data-processing system depicted in FIG. 10, in accordance with an embodiment;

FIG. 13 depicts a perspective cut-away view of RF structures that can form elements of an electron accelerator that can be adapted for use in accordance with a preferred embodiment; and

FIG. 14 depicts a perspective cut-away view of a superconducting RF structure that can also form elements of an electron accelerator adapted for use in accordance with an embodiment. The figure indicates the operating principles of such an elliptical RF cavity.

### DETAILED DESCRIPTION

The particular values and configurations discussed in the following non-limiting examples can be varied, and are cited merely to illustrate one or more embodiments and are not intended to limit the scope thereof.

Example embodiments will now be described more fully hereinafter with reference to the accompanying drawings, in which illustrative embodiments are shown. The embodiments disclosed herein can be embodied in many different forms and should not be construed as limited to the embodiments set forth herein; rather, these embodiments are provided so that this disclosure will be thorough and complete, and will fully convey the scope of the embodiments to those skilled in the art. Like numbers refer to like elements throughout.

The terminology used herein is for the purpose of describing particular embodiments only and is not intended to be limiting. As used herein, the singular forms “a”, “an”, and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Throughout the specification and claims, terms may have nuanced meanings suggested or implied in context beyond an explicitly stated meaning. Likewise, the phrase “in one embodiment” as used herein does not necessarily refer to the same embodiment and the phrase “in another embodiment” as used herein does not necessarily refer to a different embodiment. It is intended, for example, that claimed subject matter include combinations of example embodiments in whole or in part.

In general, terminology may be understood at least in part from usage in context. For example, terms, such as “and”, “or”, or “and/or,” as used herein may include a variety of meanings that may depend at least in part upon the context in which such terms are used. Typically, “or” if used to associate a list, such as A, B or C, is intended to mean A, B, and C, here used in the inclusive sense, as well as A, B or C, here used in the exclusive sense. In addition, the term “one or more” as used herein, depending at least in part upon context, may be used to describe any feature, structure, or characteristic in a singular sense or may be used to describe combinations of features, structures, or characteristics in a plural sense. In addition, the term “based on” may be understood as not necessarily intended to convey an exclusive set of factors and may, instead, allow for existence of additional factors not necessarily expressly described, again, depending at least in part on context.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Adverse weather conditions and less than optimal roadway care leads to damaged pavement over periods of time. Given the need for vehicular use in everyday life, it is essential that the primary infrastructure for vehicular transportation be kept in good condition. Conceptually, it makes sense to mount an electron beam assembly on a vehicle so that the vehicle can transport the assembly over a treatment area. However, practically speaking additional considerations including weight limitations, material costs, radiation shielding, and general environmental safety have to be considered.

The embodiments disclosed herein include systems and methods which make use of these parameters including the shield material as well as the intensity and direction of the electron beam scattering, to provide a shielded vehicle and associated safety equipment.

In certain embodiments, the integration of Artificial Intelligence (AI) can eliminate the need for some heavy shielding. AI can also be used to control the vehicle, obviating the need for an actual person to operate the machine, which can reduce possible radiation hazards.

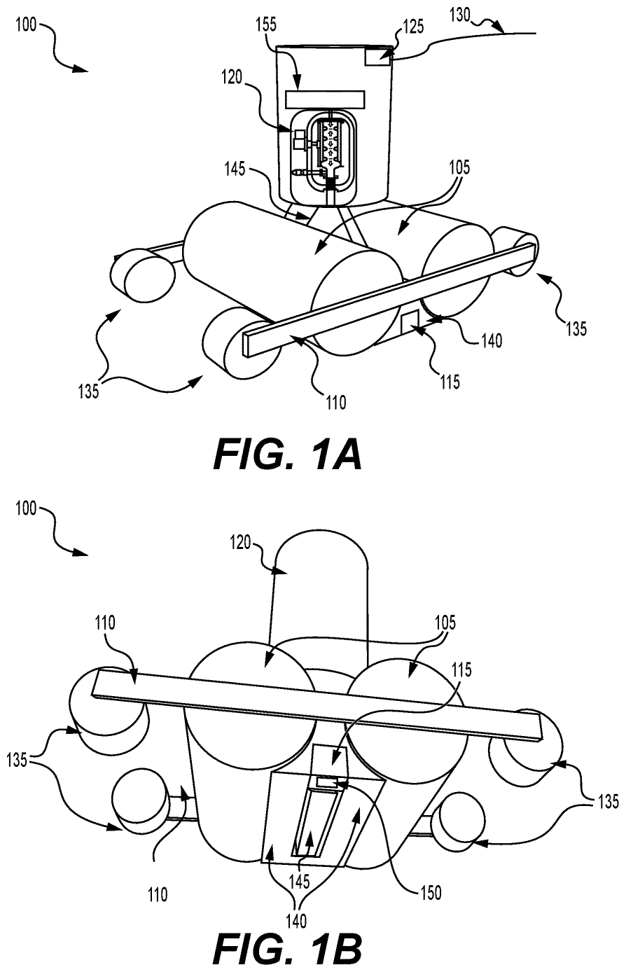

FIG. 1A and FIG. 1B illustrate aspects of a vehicle 100 that incorporates radiation shielding in its structure to allow the safe application of ionizing radiation to pavement surfaces, or other such construction structures. Specifically, the system includes a vehicle 100 with rollers 105, and a particle source 120 configured to generate a particle beam, a beam scan horn 145, the beam scan horn 145 configured to direct the terminal position of the particle beam, and a control system 155 for controlling a beam spot location of the particle beam.

As illustrated in FIG. 1A, the vehicle 100 includes shielding rollers 105 attached to a vehicle frame 110. The shielding rollers 105 provide radiation shielding front and back, while side skirt shielding 115 shield the sides. The vehicle 100 can be configured to be self-propelled or to be towed. It can carry an ionizing radiation source assembly 120, such as a particle accelerator, that can be powered by an on-board power supply 125 and/or off-vehicle supply connected by a tether 130.

The rollers 105 can provide shielding to prevent unwanted irradiation, and in certain embodiments, can also provide compaction for the surface being treated. The vehicle 100 can further include transport/maneuvering wheels 135 to allow the vehicle 100 to be maneuvered as necessary. In some embodiments, the maneuvering wheels 135 can be lowered, and the rollers 105 can be raised so that the vehicle 100 can be easily guided to a new location, on to a transport vehicle, or the like.

FIG. 1B provides a bottom perspective view of the vehicle 100. From this angle, additional lower gap shielding 140 is visible. The lower gap shielding 140 and side skirt shielding 115 are configured around a scan horn 145. The scan horn 145 is configured to direct, scan, and/or fan the ionizing radiation provided by the ionizing radiation source assembly 120.

In certain embodiments, the ionizing radiation source assembly 120, can comprise an electron accelerator that can generate electrons at an energy level up to 10 MeV. At around 10 MeV, mass attenuation of various materials for the shielding is sufficient to provide practical shielding designs. The shielding materials described herein can include steel, aluminum, titanium, copper, iron, and tungsten. In certain embodiments steel, which is primarily composed of iron, provides the optimal mass to cost ratio.

For example, in order to limit a radiation dose of less 0.25 mR/h, approximately 85 centimeters of steel is needed to protect a person 10 meters away from a 60 KW source. Limiting radiation doses to this, or lower levels, is preferrable for the safety of personnel and the work environment around the accelerator/vehicle system 100.

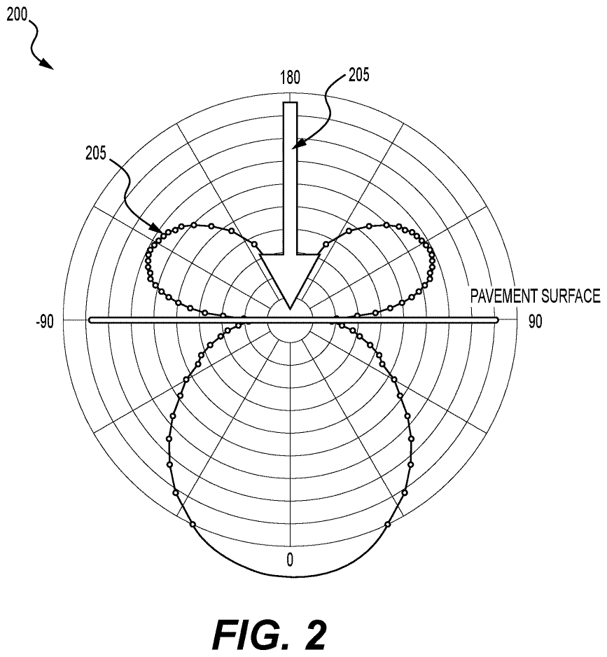

This solution is acceptable, but can be very heavy. In certain embodiments, the overall weight of the system can be reduced by varying the thickness of material around the vehicle based on the intensity of the electron beam at certain locations. FIG. 2 illustrates a chart 200 showing a trace 205 of the intensity and direction of a beam 210 scattered from pavement when the accelerator assembly 120 is operating.

With this in mind, the distribution of x-rays from the electron beam striking the pavement can be used to optimize the arrangement of the shielding on the vehicle 100 as illustrated in FIG. 1A and FIG. 1B. Sensors 150 distributed on the vehicle 100 can be used to collect data related to the X-ray distribution and intensity. In certain embodiments, a computer module can be used to analyze this data and identify necessary shielding requirements as further detailed herein. The necessary shielding disclosed herein can be determined by matching the shielding properties (e.g., material, thickness, etc.) to the X-ray intensity at all locations and directions surrounding the vehicle 100.

The vehicle 100 can comprise a shielded roller compactor. The rollers 105 can comprise compacting rollers for compacting material passing below the rollers 105. In certain embodiments, the rollers 105 can have a width ranging from 35 to 85 inches and a diameter ranging from 20 to 60 inches. In certain embodiments, the roller compactor vehicle 100 can be equipped with water tanks and sprinkler systems to wet the rollers as the machine operates and can be equipped with scrapers to remove any material buildup on the rollers.

The associated accelerator assembly 120 can be placed in a vertical position on the roller compactor vehicle 100, optionally at or near an operator cage. The space between the rollers 105 can be selected to be approximately a foot (although other dimensions are possible) to allow the electron beam from the accelerator assembly 120 to have an unobstructed path to the pavement below. Side skirt shielding 115 and lateral/gap shielding 140 can be provided in order to contain the radiation. As noted above, the thickness and composition of the side skirt shielding 115 and lateral/gap shielding 140 can be selected according to the position of the most intense radiation.

Although the system 100 can be piloted by an operator, artificial intelligence (AI) integrations can be used to allow the system 100 to be controlled remotely. In certain embodiments, this can include computer modules implemented using the computer systems illustrated as illustrated herein. For example, a perimeter can be set around the vehicle precluding entry by any human while the system is operational. The computer modules can be programmed to follow a designated route, and avoid obstructions in order to operate efficiently.

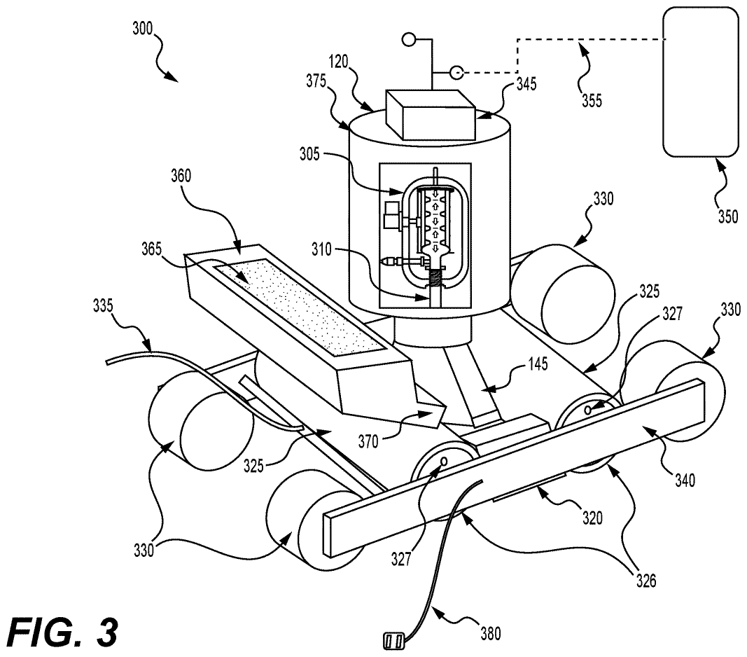

FIG. 3 illustrates additional aspects of a roller compactor vehicle system 300, with integrated radiation shielding. Some or all of the features of FIG. 1A or FIG. 1B can be parts of the system 300. The system 300 can include an ionizing radiation source assembly 120, which can include an accelerator 305. In certain embodiments, the accelerator 305 can comprise a portable superconducting radiofrequency (SRF) accelerator configured to produce an electron beam 310. The assembly 120 can further include a cryostat 375 for the SRF accelerator 305 configured to maintain the temperature of the SRF accelerator 305.

The system 300 can include a chassis 340 configured with a suspension system. The suspension system can be operably connected to the maneuvering wheels 330, rollers 325, or additional wheels, treads, etc. to regulate the load that the rollers 325 place on the underlying surface. The system 300 with the suspension can be sized to straddle a standard sized traffic lane. In certain embodiments, additional treadless tires can be used that travel on the paved lane during use.

The accelerator 305 generates an electron beam 310 which can be sent to a vacuum beam delivery horn, or scan horn 145. An exemplary horn 145 is detailed in U.S. Pat. No. 10,880,984 titled “Permanent Magnet E-Beam/X-Ray Horn”. U.S. Pat. No. 10,880,984 is herein incorporated by reference in its entirety. Other such embodiments are detailed in U.S. application Ser. No. 17/116,880 titled “Permanent Magnet E-Beam/X-Ray Horn”. U.S. application Ser. No. 17/116,880 is herein incorporated by reference in its entirety. The delivery horn 145 can be used to narrow the beam for example, to treat a longitudinal seam or some other non-standard shape.

The particle beam 310 can be used to treat the underlying surface (e.g., asphalt, pavement, or other such underlayment) to cure the material as necessary. For example, the electron beam 310 can heat an underlying road surface, or can heat the bottom and edges of potholes. In some embodiments, the heat can improve the bond between the old and new materials on the surfaces. The beam 310 can further be used, once the material has been deposited on the roadway, to cross link pavement material. Alternatively, the beam 310 can cross link material that has been filled and compacted in a pothole.

In certain embodiments a control module 345 associated with the accelerator 305 can be used to control the dose of irradiating beam provided by the accelerator 305. The control module 345 can be a remotely controllable computer system connected to an external device 350, via a wired or wireless connection 355.

In certain embodiments the control module 345 can also be used to control the movement of the system 300 over the underlying surface. This can include the acceleration, deceleration, speed, and direction of the system 300. By controlling the speed, and power of the irradiating beam, the control module 345 can be used to ensure the necessary dose of beam is supplied to a given area (e.g., a pothole) as the vehicle 300 passes over.

The vehicle 300 can be configured with a hopper 360 configured to deliver a desired material 365 (e.g., asphalt, cement, etc.) to the desired location below the system 300. The hopper 360 can include a chute 370 to deliver the material 365 to a location (e.g., a pothole) below the system 300. The electron beam can heat the material, and it can then be compacted with the rollers 325.

Integrated shielding 320 can be provided between compactor rollers 325. The integrated shielding 320 can be configured with a compactor roller side profile that mirrors that of the curved shape of the compactor rollers 325 to minimize unshielded space between the rollers 325. It should be appreciated that, in other embodiments, all shielding can be suspended from the vehicle chassis with a very small gap at the surface. The shape and profile of the shielding 320 components provide appropriate shielding to the vehicle as well as all parts of accelerator assembly 120, beam distribution system, operator, and bystanders.

In addition, the rollers 325 can be configured to include shielding 326 on their exterior surfaces. In certain embodiments, the shielding rollers 325 can be hollow and can be configured with a valve 327 or suitable opening so that they can be filled with a liquid or granular material to add weight and shielding value if desired. The valve(s) 327 can also be used to empty the roller(s) 325 after use to reduce transport weight of the system.

The roller size (in particular the width) can be selected to treat a complete lane, or partial lane of a roadway. Multiple passes may be required, or multiple machines can be used to treat the complete lane.

The system 300 can be fitted with maneuvering wheels 330. The additional wheels 330 can be used for transporting the system 300 from one location to another. The shielding rollers 325 can be raised from the underlying surface while the system 300 is being transported to or from a job site.

In certain embodiments, the maneuvering wheels 330 and the shielding and/or compacting rollers 325 can be self-propelled. In such embodiments a motor can be provided to drive the compacting rollers 325 or maneuvering wheels 330. In other embodiments the system 300 can include a tether 335 to a tow vehicle or can be connected to the power gird with a power tether.

For example, in certain embodiments power can be configured on-board, either as a separate generator or prime mover. Power can also, or alternatively, be provided by separate electric generator and supplied through a tethered cable 380. Power can be supplied through the tethered cable connected to a local power grid.

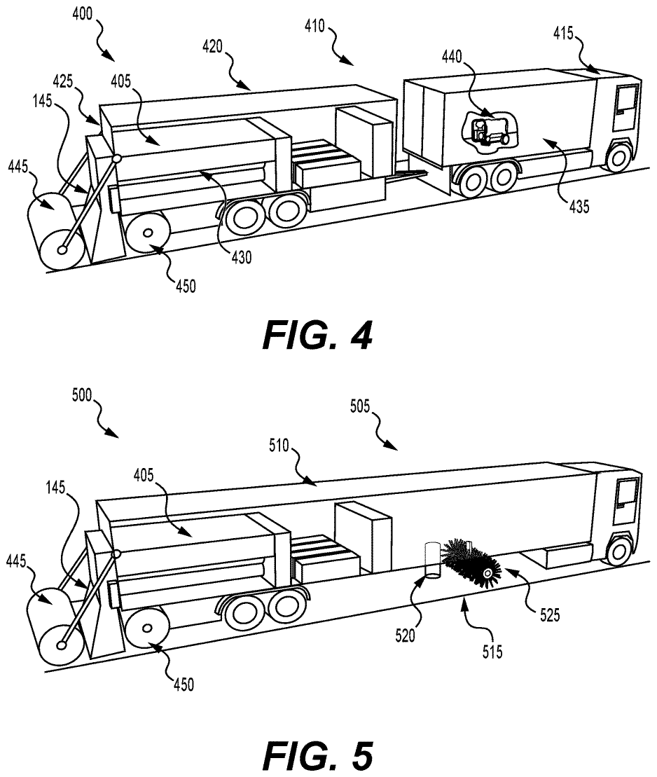

FIGS. 4-7 illustrate additional aspects of the disclosed embodiments in a system 400. For example, FIG. 4 illustrates an accelerator assembly 405 configured in a vehicle 410. In this embodiment, the vehicle 410 comprises a semi-truck 415 with a trailer 420. The accelerator assembly 405 can be provided in the trailer 420, and can be configured with a beam line and/or horn 145 at its back end 425. Furthermore, the accelerator assembly 405 can be configured in a compartment 430 of the vehicle trailer 420, and the generator 435 for the accelerator 405 can be housed in another compartment 440 of the trailer 420.

A first shielding roller 445 can be arranged behind the beam line, and a second shielding roller 450 can be arranged in front of the beam line, and below the trailer 420. The shielding rollers can be configured to compact the surface being treated by the accelerator, and in addition, can be used for shielding any irradiation that results from the accelerator.

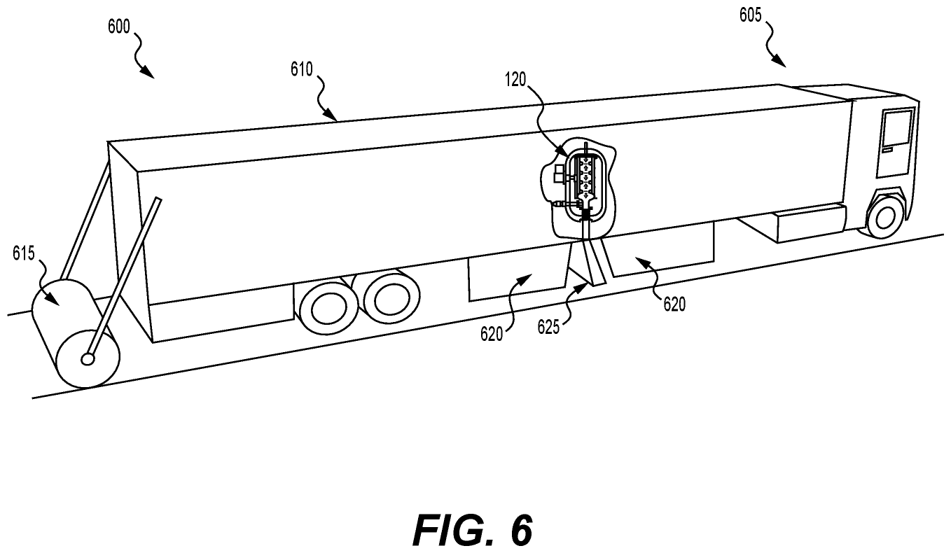

FIG. 5 illustrates another such embodiment of a system 500 with a vehicle 505 with a single trailer 510. As illustrated in FIG. 5, various cleaning tools 515 can be incorporated in the system 500 to provide surface cleaning functions. It should be noted, similar tools can be integrated with any of the embodiments illustrated herein.

The system 500 can include a compressed gas (e.g., air) distributor 520 which can comprise a compressed gas tank and distributing regulator, used to blow high pressure gas onto surfaces below the vehicle 500 for cleaning/clearing debris below the vehicle 500. Likewise, a reciprocating or rotating brush 525 can be configured on the vehicle 500 and driven by an electric motor or the like. The brush 525 can be used to brush the surfaces below the vehicle 500 to clear debris before or after the surface is dosed by irradiation.

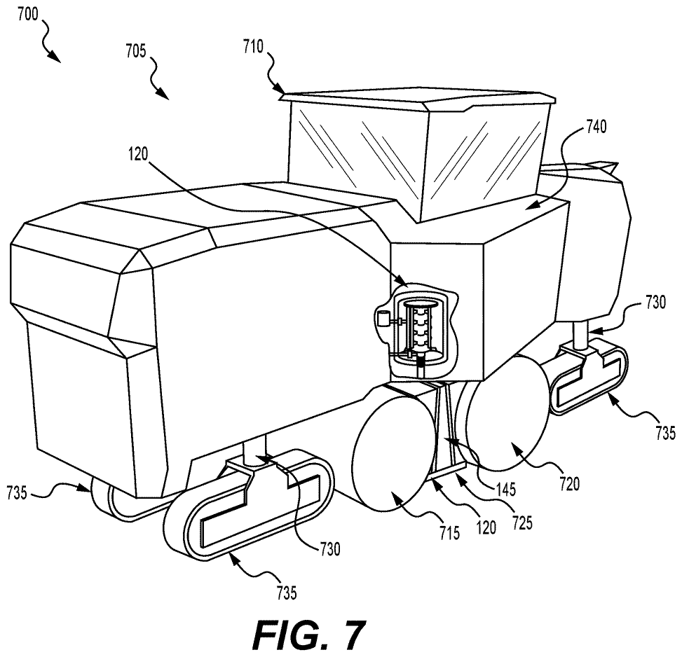

FIG. 6 illustrates another embodiment of a system 600 wherein the accelerator assembly 120 is configured in the middle of a trailer 610 associated with a vehicle 605. In this embodiment, the rollers 615 can be used for compacting only and additional shielding 620 can be configured as non-roller shielding 620 can have an external profile shape matching that of the scan horn 625.

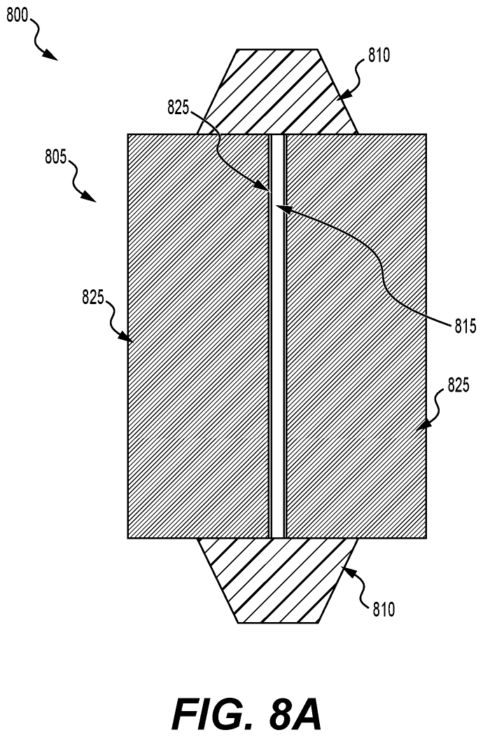

FIG. 7 illustrates another embodiment of a system 700, comprising a paving system 700. In such embodiments a paving system 700 can comprise a track driven vehicle 705 with a pilot cage 710. The accelerator assembly 120 can be configured at or near the pilot cage 710. In certain embodiments, the paving system 700 can be a purpose built, track driven vehicle 705.

A first shielding roller 715, as detailed with respect to other embodiments, can be configured in front of the accelerator assembly 120, and a second shielding roller 720 can be configured behind the accelerator assembly 120. The horn 145, can be configured with proximate shielding 725. The proximate shielding 725 can be configured to fit the spaces around the surrounding the first roller 715, second roller 720 and the horn 145.

The vehicle 705 can include legs 730, with tracked drivers 735. The tracked assembly drives the vehicle 705 over the desired area. The first roller 715 and second roller 720 can be raised or lowered as necessary to compact the surface below being treated by the accelerator assembly 120. Additional pilot shielding 740 can be provided above the accelerator assembly 120 to reduce the potential for scattered irradiation entering the pilot cage 710. It should be appreciated that, in other embodiments, the rollers and accelerator can be retrofitted to a track driven vehicle.

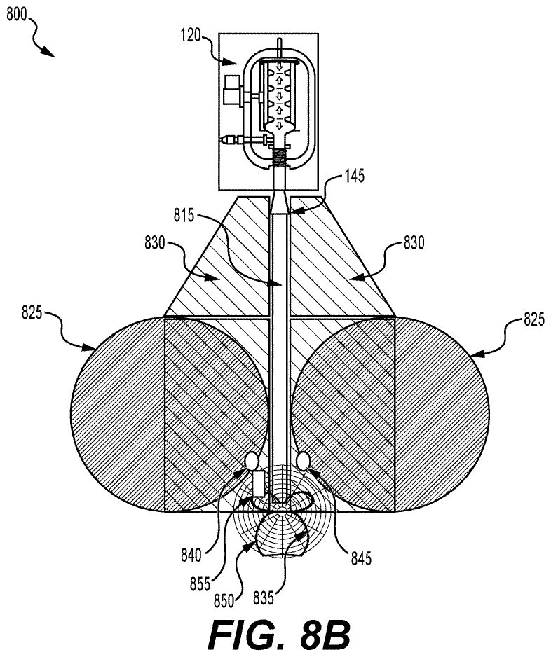

FIGS. 8A and 8B illustrate exemplary embodiments of a system 800 for irradiation built into a shielded roller assembly 805. FIG. 8A illustrates a top view of the system 800. In such embodiments, lateral shielding 810 (e.g., lead shielding) can be provided on the sides of the shielded roller assembly 805, where irradiation levels are highest. In certain embodiments, lower density shielding (e.g., steel paneling) can be used for other shielding where irradiation levels are lower. The electron beam 815 is configured with a beam path 820 that passes between the shielding rollers 825 onto the surface below. It should be noted that the electron beam 815 can be spread or scanned across the space between the lateral shielding 810.

FIG. 8B illustrates a side perspective view of the shielded roller assembly 805. From this view the accelerator assembly 120 is visible above the top shielding 830. The beam 815 passes through scan horn 145. Additional gap shielding 835 can be provided between the beam 815 and shielding rollers 825.

In certain embodiments, a camera 840, and/or radiation sensors 845 can be disposed on the shielded roller assembly 805, to monitor the radiation levels 850. The radiation sensor 845 can be used to collect data about the irradiation levels to provide warnings if exposure levels are higher than anticipated, for example if shielding fails. Likewise, cameras 840 can be used to view the surface below the conveyance to verify the necessary treatment dose has been applied. Temperature sensors 855 can also be used in certain embodiments.

In certain embodiments, control of the systems disclosed herein can be provided remotely. In such cases an external operator can use a computer system and associated driver modules coupled to the controller of the vehicle to drive the vehicle. The external operator can also use the computer system to control beam power and associated treatment. This can be facilitated with an on-board operator.

Alternatively, the systems disclosed herein can have onboard controls, and can be operated locally by an operator riding the vehicle. Additional local shielding for the operator may be incorporated to meet occupational exposure requirements.

In certain embodiments, remote sensors for viewing of the beam interaction areas may be incorporated, to monitor the irradiation process using cameras 840, additional sensors 845 can comprise irradiation sensors, x-ray sensors, temperature sensors or the like. Sensors 845 can directly monitor the irradiation region, or sensors can monitor radiation or other direct or indirect parameters (i.e., beam current). Data from the sensors can be used to provide feedback for motion control, beam current control, targeting, etc.

Optical sensors can be disposed at various locations on and around the vehicle including on the lower facing surfaces of the vehicle, sides of the vehicle, and top of the vehicle. The cameras/image sensors therefore have a direct view, views through shield windows, and views through optical coupling.

The combined sensor array can be used to monitor various parameters including reflected x-ray intensity, reflected x-ray spectra, drag on a mechanical finger as it passes over or through pavement as the machine progresses to monitor the amount of material processing completed, as well as other user defined parameters.

The sensors 845 can also provide necessary safety data. In certain embodiments, this can include on-board radiation detecting sensors on the outside of the shielding which can monitor radiation passing through shielding to ensure regulatory compliance and personnel protection. The sensors can also be used to measure the amount of shielding required as determined by applicable regulations, and potential administratively controlled personnel exclusion zones during operation.

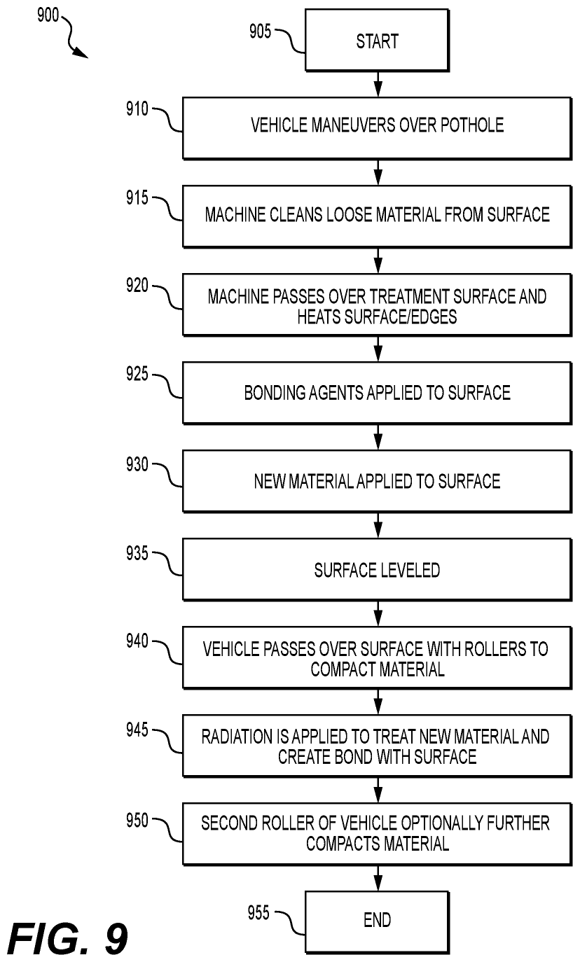

FIG. 9 illustrates aspects of a method 900 for treating a surface, such as a roadway, in accordance with the disclosed embodiments and using the systems disclosed herein. It should be appreciated that this flow chart is meant to be exemplary, and that the systems disclosed herein could be used for numerous other applications in certain embodiments. Likewise, any or all of these steps may be integrated or performed separately and in other orders, without departing from the scope of the embodiments. The method starts at 905.

At step 910 is a system, including any of the systems illustrated in FIGS. 1-8 can be maneuver over the surface to be treated. In some cases, this could be a pothole but other treatment conditions, like a new road, new lane, or new surface, are all possible. Next, at step 915 the system can be used to clean loose material from the underlying surface. This can be done with mechanical means such as wire brushes as detailed supra, and/or with compressed air jets.

Next, at step 920 an accelerator assembly associated with the system can be used to irradiate (and heat) the underlying surface, edges, and bottom of the roadway (e.g., pothole) to improve adhesion. Bonding agents can optionally be applied to the surface as necessary at step 925. With the underlying surface prepared, new asphalt material (or other such substance can be applied to the roadway at step 930. At step 935, the new material can optionally be leveled with a scraper or similar device.

With the new material deposited and leveled, at step 940 the system can pass over the material. Optionally, the front roller of the system is used to compact the material. Radiation is then applied to treat the new surface at step 945. This can include irradiating, new asphalt with an electron beam to create a bond with the old surface. Optionally, the second roller (serving as a compacting roller) can also be driven over the treated surface to complete the treatment at step 950. The method ends at 955.

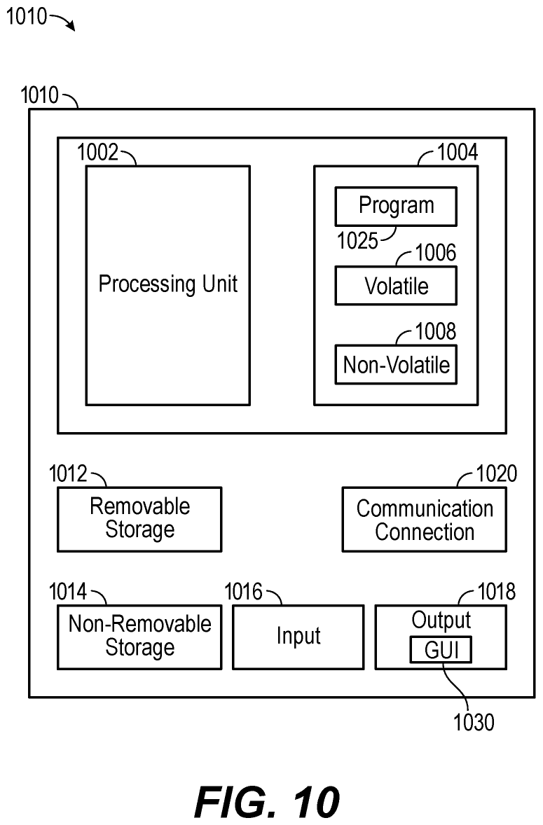

FIGS. 10-12 are provided as exemplary diagrams of data-processing environments in which embodiments of the present invention may be implemented. It should be appreciated that FIGS. 10-12 are only exemplary and are not intended to assert or imply any limitation with regard to the environments in which aspects or embodiments of the disclosed embodiments may be implemented. Many modifications to the depicted environments may be made without departing from the spirit and scope of the disclosed embodiments.

A block diagram of a computer system 1000 that executes programming for implementing parts of the methods and systems disclosed herein is shown in FIG. 10. A computing device in the form of a computer 1010 configured to interface with sensors, peripheral devices, and other elements disclosed herein may include one or more processing units 1002, memory 1004, removable storage 1012, and non-removable storage 1014. Memory 1004 may include volatile memory 1006 and non-volatile memory 1008. Computer 1010 may include or have access to a computing environment that includes a variety of transitory and non-transitory computer-readable media such as volatile memory 1006 and non-volatile memory 1008, removable storage 1012 and non-removable storage 1014. Computer storage includes, for example, random access memory (RAM), read only memory (ROM), erasable programmable read-only memory (EPROM) and electrically erasable programmable read-only memory (EEPROM), flash memory or other memory technologies, compact disc read-only memory (CD ROM), Digital Versatile Disks (DVD) or other optical disk storage, magnetic cassettes, magnetic tape, magnetic disk storage, or other magnetic storage devices, or any other medium capable of storing computer-readable instructions as well as data including image data.

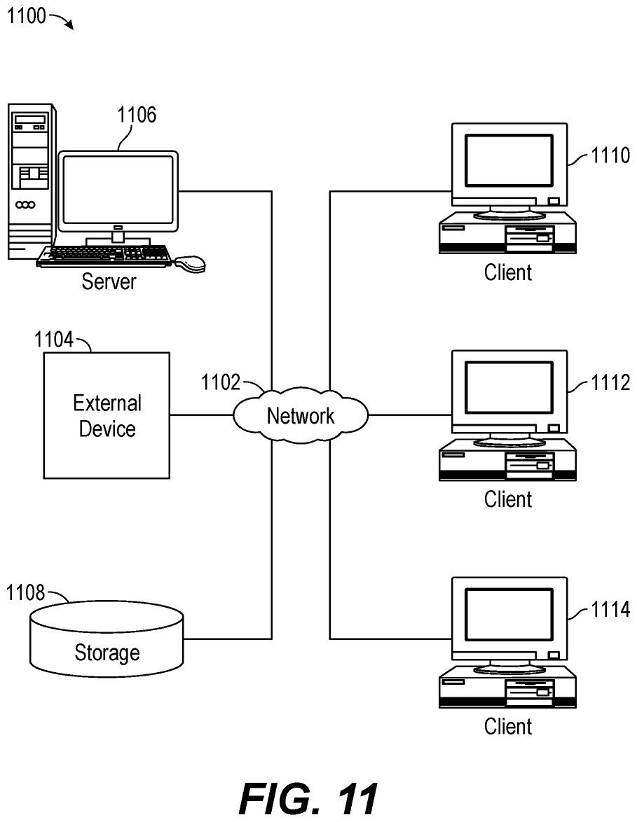

Computer 1010 may include or have access to a computing environment that includes input 1016, output 1018, and a communication connection 1020. The computer may operate in a networked environment using a communication connection 1020 to connect to one or more remote computers, remote sensors, detection devices, hand-held devices, multi-function devices (MFDs), mobile devices, tablet devices, mobile phones, Smartphones, or other such devices. The remote computer may also include a personal computer (PC), server, router, network PC, RFID enabled device, a peer device or other common network node, or the like. The communication connection may include a Local Area Network (LAN), a Wide Area Network (WAN), Bluetooth connection, or other networks. This functionality is described more fully in the description associated with FIG. 11 below.

Output 1018 is most commonly provided as a computer monitor, but may include any output device. Output 1018 and/or input 1016 may include a data collection apparatus associated with computer system 1000. In addition, input 1016, which commonly includes a computer keyboard and/or pointing device such as a computer mouse, computer track pad, or the like, allows a user to select and instruct computer system 1000. A user interface can be provided using output 1018 and input 1016. Output 1018 may function as a display for displaying data and information for a user, and for interactively displaying a graphical user interface (GUI) 1030.

Note that the term “GUI” generally refers to a type of environment that represents programs, files, options, and so forth by means of graphically displayed icons, menus, and dialog boxes on a computer monitor screen. A user can interact with the GUI to select and activate such options by directly touching the screen and/or pointing and clicking with a user input device 1016 such as, for example, a pointing device such as a mouse and/or with a keyboard. A particular item can function in the same manner to the user in all applications because the GUI provides standard software routines (e.g., module 1025) to handle these elements and report the user's actions. The GUI can further be used to display the electronic service image frames as discussed below.

Computer-readable instructions, for example, program module or node 1025, which can be representative of other modules or nodes described herein, are stored on a computer-readable medium and are executable by the processing unit 1002 of computer 1010. Program module or node 1025 may include a computer application. A hard drive, CD-ROM, RAM, Flash Memory, and a USB drive are just some examples of articles including a computer-readable medium.

FIG. 11 depicts a graphical representation of a network of data-processing systems 1100 in which aspects of the present invention may be implemented. Network data-processing system 1100 is a network of computers or other such devices such as mobile phones, smartphones, sensors, detection devices, controllers, and the like in which embodiments of the present invention may be implemented. Note that the system 1100 can be implemented in the context of a software module such as program module 1025. The system 1100 includes a network 1102 in communication with one or more clients 1110, 1112, and 1114. Network 1102 may also be in communication with one or more device 1104, servers 1106, and storage 1108. Network 1102 is a medium that can be used to provide communications links between various devices and computers connected together within a networked data processing system such as computer system 1000. Network 1102 may include connections such as wired communication links, wireless communication links of various types, fiber optic cables, quantum, or quantum encryption, or quantum teleportation networks, etc. Network 1102 can communicate with one or more servers 1106, one or more external devices such as a controller, actuator, sensor, or other such device 1104, and a memory storage unit such as, for example, memory or database 1108. It should be understood that device 1104 may be embodied as a detector device, microcontroller, controller, receiver, transceiver, or other such device.

In the depicted example, device 1104, server 1106, and clients 1110, 1112, and 1114 connect to network 1102 along with storage unit 1108. Clients 1110, 1112, and 1114 may be, for example, personal computers or network computers, handheld devices, mobile devices, tablet devices, smartphones, personal digital assistants, microcontrollers, recording devices, MFDs, etc. Computer system 1000 depicted in FIG. 10 can be, for example, a client such as client 1110 and/or 1112.

Computer system 1000 can also be implemented as a server such as server 1106, depending upon design considerations. In the depicted example, server 1106 provides data such as boot files, operating system images, applications, and application updates to clients 1110, 1112, and/or 1114. Clients 1110, 1112, and 1114 and external device 1104 are clients to server 1106 in this example. Network data-processing system 1100 may include additional servers, clients, and other devices not shown. Specifically, clients may connect to any member of a network of servers, which provide equivalent content.

In the depicted example, network data-processing system 1100 is the Internet with network 1102 representing a worldwide collection of networks and gateways that use the Transmission Control Protocol/Internet Protocol (TCP/IP) suite of protocols to communicate with one another. At the heart of the Internet is a backbone of high-speed data communication lines between major nodes or host computers consisting of thousands of commercial, government, educational, and other computer systems that route data and messages. Of course, network data-processing system 1100 may also be implemented as a number of different types of networks such as, for example, an intranet, a local area network (LAN), or a wide area network (WAN). FIGS. 10 and 11 are intended as examples and not as architectural limitations for different embodiments of the present invention.

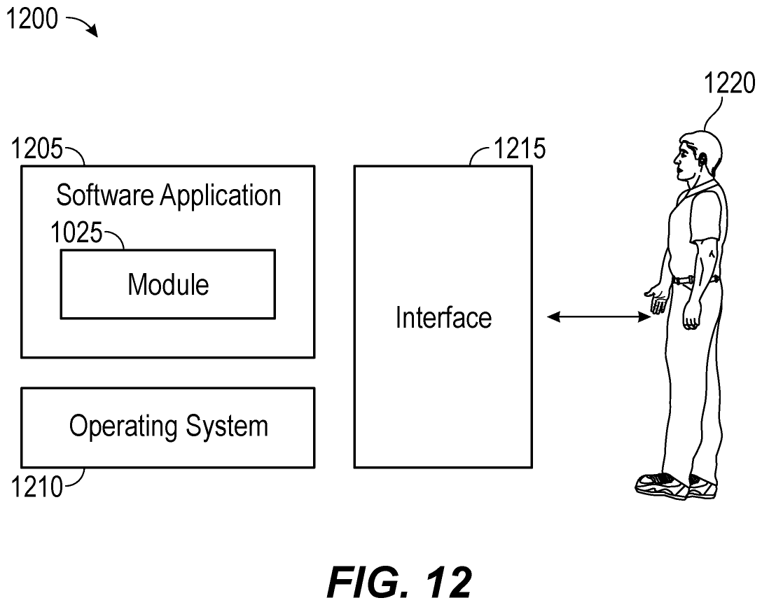

FIG. 12 illustrates a software system 1200, which may be employed for directing the operation of the data-processing systems such as computer system 1000 depicted in FIG. 10. Software application 1205, may be stored in memory 1004, on removable storage 1012, or on non-removable storage 1014 shown in FIG. 10, and generally includes and/or is associated with a kernel or operating system 1210 and a shell or interface 1215. One or more application programs, such as module(s) or node(s) 1025, may be “loaded” (i.e., transferred from removable storage 1014 into the memory 1004) for execution by the data-processing system 1000. The data-processing system 1000 can receive user commands and data through user interface 1215, which can include input 1016 and output 1018, accessible by a user 1220. These inputs may then be acted upon by the computer system 1000 in accordance with instructions from operating system 1210 and/or software application 1205 and any software module(s) 1025 thereof.

Generally, program modules (e.g., module 1025) can include, but are not limited to, routines, subroutines, software applications, programs, objects, components, data structures, etc., that perform particular tasks or implement particular abstract data types and instructions. Moreover, those skilled in the art will appreciate that elements of the disclosed methods and systems may be practiced with other computer system configurations such as, for example, hand-held devices, mobile phones, smart phones, tablet devices, multi-processor systems, printers, copiers, fax machines, multi-function devices, data networks, microprocessor-based or programmable consumer electronics, networked personal computers, minicomputers, mainframe computers, servers, medical equipment, medical devices, and the like.

Note that the term module or node as utilized herein may refer to a collection of routines and data structures that perform a particular task or implements a particular abstract data type. Modules may be composed of two parts: an interface, which lists the constants, data types, variables, and routines that can be accessed by other modules or routines; and an implementation, which is typically private (accessible only to that module), and which includes source code that actually implements the routines in the module. The term module may also simply refer to an application such as a computer program designed to assist in the performance of a specific task such as word processing, accounting, inventory management, etc., or a hardware component designed to equivalently assist in the performance of a task.

The interface 1215 (e.g., a graphical user interface 1030) can serve to display results, whereupon a user 1220 may supply additional inputs or terminate a particular session. In some embodiments, operating system 1210 and GUI 1030 can be implemented in the context of a “windows” system. It can be appreciated, of course, that other types of systems are possible. For example, rather than a traditional “windows” system, other operation systems such as, for example, a real time operating system (RTOS) more commonly employed in wireless systems may also be employed with respect to operating system 1210 and interface 1215. The software application 1205 can include, for example, module(s) 1025, which can include instructions for carrying out steps or logical operations such as those shown and described herein.

The following description is presented with respect to embodiments of the present invention, which can be embodied in the context of, or require the use of a data-processing system such as computer system 1000, in conjunction with program module 1025, and data-processing system 1100 and network 1102 depicted in FIGS. 10-3. The present invention, however, is not limited to any particular application or any particular environment. Instead, those skilled in the art will find that the systems and methods of the present invention may be advantageously applied to a variety of system and application software including database management systems, word processors, and the like. Moreover, the present invention may be embodied on a variety of different platforms including Windows, Macintosh, UNIX, LINUX, Android, Arduino, and the like. Therefore, the descriptions of the exemplary embodiments, which follow, are for purposes of illustration and not considered a limitation.

U.S. Pat. No. 9,186,645, titled “METHOD AND SYSTEM FOR IN-SITU CROSS LINKING OF POLYMERS, BITUMEN AND SIMILAR MATERIALS TO INCREASE STRENGTH, TOUGHNESS AND DURABILITY VIA IRRADIATION WITH ELECTRON BEAMS FROM MOBILE ACCELERATORS,” issued on Nov. 17, 2015 describes systems and methods for treating and strengthening a material, the systems and methods comprising a mobile unit, an electron gun that emits a beam of electrons, an electron accelerator integrated with the mobile unit that is positioned to accelerate the beam of electrons, and a beam extraction device comprising a scan coil that emits the accelerated beam of electrons, where the beam extracting device is positioned on the mobile unit to irradiate the surface of, and treat in-situ, a material located proximate to the mobile unit, wherein irradiation of the material by the beam of electrons results in in-situ cross-linking of the material and therefore a strengthening and increased durability of the material. U.S. Pat. No. 9,186,645 is herein incorporated by reference in its entirety.

U.S. Pat. No. 9,340,931, titled “METHOD AND SYSTEM FOR IN-SITU CROSS LINKING OF POLYMERS, BITUMEN AND SIMILAR MATERIALS TO INCREASE STRENGTH, TOUGHNESS AND DURABILITY VIA IRRADIATION WITH ELECTRON BEAMS FROM MOBILE ACCELERATORS,” issued on May 17, 2016 describes systems and methods for treating and strengthening a material, the systems and methods comprising a mobile unit, an electron gun that emits a beam of electrons, an electron accelerator integrated with the mobile unit that is positioned to accelerate the beam of electrons, and a beam extraction device comprising a scan coil that emits the accelerated beam of electrons, where the beam extracting device is positioned on the mobile unit to irradiate the surface of, and treat in-situ, a material located proximate to the mobile unit, wherein irradiation of the material by the beam of electrons results in in-situ cross-linking of the material and therefore a strengthening and increased durability of the material. U.S. Pat. No. 9,340,931 is herein incorporated by reference in its entirety.

U.S. Pat. No. 10,070,509, titled “COMPACT SRF BASED ACCELERATOR,” issued on Sep. 4, 2018, describes a particle accelerator comprising an accelerator cavity, an electron gun, and a cavity cooler configured to at least partially encircle the accelerator cavity. A cooling connector and an intermediate conduction layer are formed between the cavity cooler and the accelerator cavity to facilitate thermal conductivity between the cavity cooler and the accelerator cavity. The embodiments disclosed therein teach a viable, compact, robust, high-power, high-energy electron-beam, or x-ray source. The disclosed advances are integrated into a single design, that enables compact, mobile, high-power electron accelerators. U.S. Pat. No. 10,070,509 is herein incorporated by reference in its entirety.

U.S. Pat. No. 11,123,921, titled “METHOD AND SYSTEM FOR CROSS-LINKING OF MATERIALS TO PRODUCE THREE-DIMENSIONAL FEATURES VIA ELECTRON BEAMS FROM MOBILE ACCELERATORS,” issued on Sep. 21, 2021, describes a particle accelerator used in combination with control and delivery systems to produce arbitrary functional or ornamental three-dimensional features. U.S. Pat. No. 11,123,921 is herein incorporated by reference in its entirety.

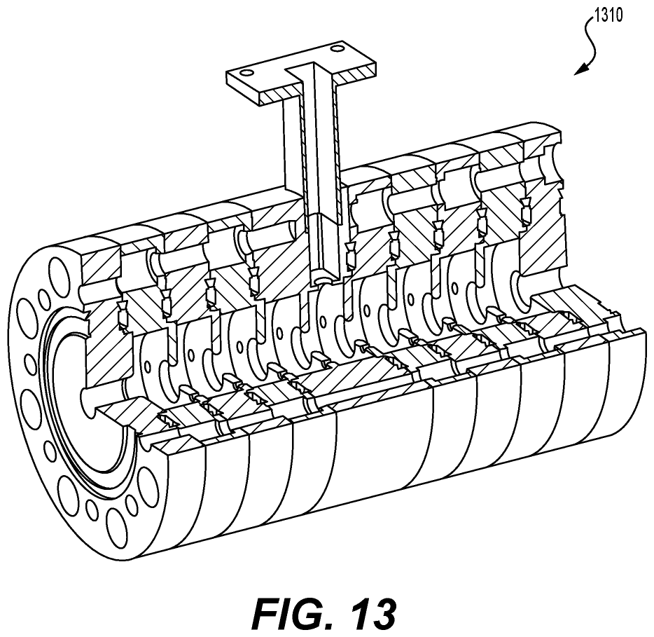

FIG. 13 illustrates a perspective cut-away view of an RF structure 1310 that can form elements of an electron accelerator that can be adapted for use in accordance with embodiments disclosed herein. Note that RF accelerator and electron gun structures can be employed to produce electron beams of the required energy for implementation of the disclosed embodiments. An electron accelerator, for example, that employs the RF structure 1310 can accelerate electrons generated from an electron gun with RF electric fields in resonant cavities sequenced such that the electrons are accelerated due to an electric field present in each cavity as the electron traverses the cavity to reach a beam extraction device.

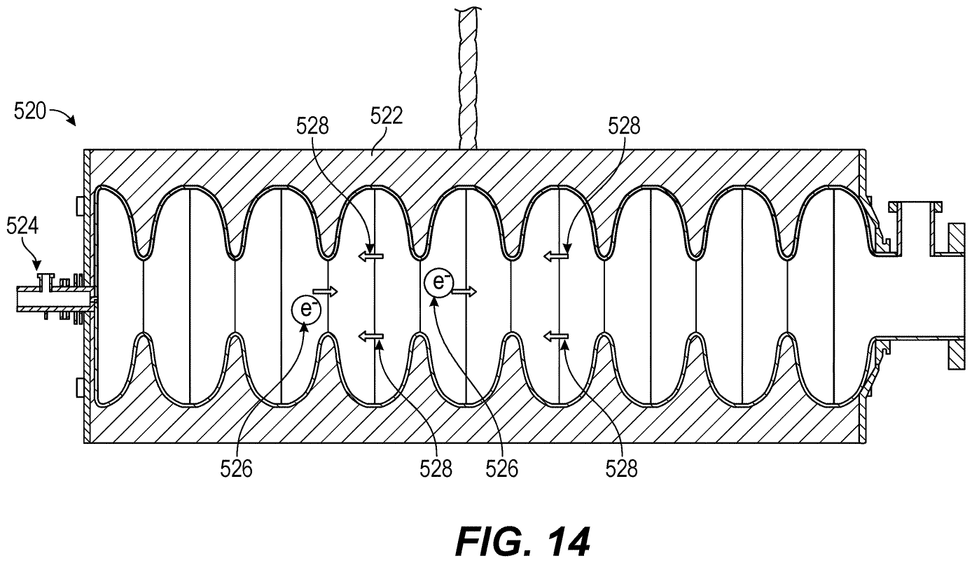

FIG. 14 illustrates a perspective cut-away view of an 8.5 cell elliptical superconducting RF structure 1420 that can also form elements of an electron accelerator adapted for use in accordance with an embodiment. Note that varying embodiments can employ alternative cavity geometries and/or cell numbers. FIG. 14 generally indicates the operating principles of an elliptical RF cavity. Advancements in SRF technology can enable even more compact and efficient accelerators for this application.

The RF structure 1420 of FIG. 14 demonstrates the principle of operation in which alternating RF electric fields can be arranged to accelerate groups of electrons timed to arrive in each cavity when the electric field in that cavity causes the electrons to gain additional energy. In the particular embodiment shown in FIG. 14, a voltage generator can induce an electric field within the RF cavity. Its voltage can oscillate, for example, with a radio frequency of 1.3 Gigahertz or 1.3 billion times per second. An electron source 1424 can inject particles into the cavity in phase with the variable voltage provided by the voltage generator of the RF structure 1420. Arrow(s) 1426 shown in FIG. 14 indicate that the electron injection and cavity RF phase is adjusted such that electrons experience or “feel” an average force that accelerates them in the forward direction, while arrow(s) 1428 indicate that electrons are not present in a cavity cell when the force is in the backwards direction. The structure 1420 can be cooled with a conduction cooling system 1422.

It can be appreciated that the example RF structures 1310 and 1420, respectively shown in FIGS. 13-14, represent examples only and that electron accelerators of other types and configurations/structures/frequencies may be implemented in accordance with alternative embodiments. That is, the disclosed embodiments are not limited structurally to the example electron accelerator structures 1310, 1420, respectively shown in FIGS. 13-14, but represent merely one possible type of structure that may be employed with particular embodiments. Alternative embodiments may vary in structure, arrangement, frequency, and type of utilized accelerators, RF structures, and so forth.

Based on the foregoing, it can be appreciated that a number of embodiments, preferred and alternative, are disclosed herein. In an embodiment, a system comprises a vehicle comprising at least one roller and a particle source configured to generate a particle beam, a beam scan horn, the beam scan horn configured to direct the terminal position of the particle beam, and a control system for controlling a beam spot location of the particle beam.

In an embodiment, the particle source further comprises a particle accelerator. In an embodiment, the particle accelerator comprises an electron beam accelerator. In an embodiment, the particle beam comprises an electron beam.

In an embodiment, the vehicle further comprises radiation shielding configured proximate to a terminus of the particle beam.

In an embodiment, the at least one roller further comprises a first roller and a second roller. In an embodiment, each of the first roller and the second roller are hollow. In an embodiment, each of the first roller and the second roller further comprise shielding on their external surface. In an embodiment, the at least one roller further comprises a radiation shielding roller.

In an embodiment, the vehicle further comprises at least one additional wheel configured for maneuvering the vehicle when not in use.

In another embodiment, a system comprises a vehicle comprising at least two shielding rollers and a particle accelerator mounted to the vehicle and oriented so that a beam from the particle accelerator points downward, s, ide skirt shielding, lower gap shielding, and a beam scan horn, the beam scan horn configured to direct the terminal position of the particle beam. In an embodiment, the particle accelerator comprises an electron beam accelerator configured to produce an electron beam.

In an embodiment, each of the at least two shielding rollers further comprise shielding on their external surface.

In an embodiment, the system further comprises at least one radiation sensor configured to measure radiation between the shielding rollers. In an embodiment, the system further comprises at least one camera configured to capture images between the shielding rollers.

In an embodiment, of the system the vehicle further comprises a chassis and at least one additional wheel configured for maneuvering the vehicle when not in use.

In an embodiment, a system comprises a vehicle comprising at least two shielding rollers, a particle source configured to generate a particle beam, at least one additional wheel configured for maneuvering the vehicle when not in use, and a control system for controlling the vehicle and for controlling a beam spot location of the particle beam, and at least one sensor configured to measure radiation between the at least two shielding rollers.

In an embodiment, the vehicle further comprises radiation shielding configured proximate to a terminus of the particle beam. In an embodiment, each of the at least two shielding roller further comprise radiation shielding rollers.

In the at least one sensor comprises at least one of irradiation sensors, x-ray sensors, temperature sensors, and cameras.

It should be appreciated that variations of the above-disclosed and other features and functions, or alternatives thereof, may be desirably combined into many other different systems or applications. It should be understood that various presently unforeseen or unanticipated alternatives, modifications, variations, or improvements therein may be subsequently made by those skilled in the art which are also intended to be encompassed by the following claims.

What is claimed is:

1. A system comprising:
a vehicle comprising:
at least one roller; and
a particle source configured to generate a particle beam;
a beam scan horn, the beam scan horn configured to direct the terminal position of the particle beam; and
a control system for controlling a beam spot location of the particle beam.

2. The system of claim 1 wherein the particle source further comprises:
a particle accelerator.

3. The system of claim 1 wherein the particle accelerator comprises:
an electron beam accelerator.

4. The system of claim 1 wherein the particle beam comprises:
an electron beam.

5. The system of claim 1 wherein the vehicle further comprises:
radiation shielding configured proximate to the terminal position of the particle beam.

6. The system of claim 1 wherein the at least one roller further comprises:
a first roller; and
a second roller.

7. The system of claim 6 wherein each of the first roller and the second roller are hollow.

8. The system of claim 6 wherein each of the first roller and the second roller further comprise:
shielding on their external surface.

9. The system of claim 1 wherein the at least one roller further comprises:
a radiation shielding roller.

10. The system of claim 1 wherein the vehicle further comprises:
at least one additional wheel configured for maneuvering the vehicle when not in use.

11. A system comprising:
a vehicle comprising:
at least two shielding rollers; and
a particle accelerator mounted to the vehicle and oriented so that a beam from the particle accelerator points downward;
side skirt shielding;
lower gap shielding; and
a beam scan horn, the beam scan horn configured to direct the terminal position of the particle beam.

12. The system of claim 11 wherein the particle accelerator comprises:
an electron beam accelerator configured to produce an electron beam.

13. The system of claim 11 wherein each of the at least two shielding rollers further comprise:
shielding on their external surfaces.

14. The system of claim 11 further comprising:
at least one radiation sensor configured to measure radiation between the shielding rollers.

15. The system of claim 11 further comprising:
at least one camera configured to capture images between the shielding rollers.

16. The system of claim 1 wherein the vehicle further comprises:
a chassis; and
at least one additional wheel configured for maneuvering the vehicle when not in use.

17. A system comprising:
a vehicle comprising:
at least two shielding rollers;
a particle source configured to generate a particle beam; and
at least one additional wheel configured for maneuvering the vehicle when not in use;
a control system for controlling the vehicle and for controlling a beam spot location of the particle beam; and
at least one sensor configured to measure radiation between the at least two shielding rollers.

18. The system of claim 17 wherein the vehicle further comprises:
radiation shielding configured proximate to a terminus of the particle beam.

19. The system of claim 17 wherein each of the at least two shielding rollers further comprise:
radiation shielding rollers.

20. The system of claim 17 wherein the at least one sensor comprises at least one of:
irradiation sensors;
x-ray sensors;
temperature sensors; and
cameras.
